(19) United States
(12) Patent Application Publication
(10) Pub. No.: US 2017/0064875 A1
(43) Pub. Date: Mar. 2, 2017

(54) Mobile Computer Cabinet with Integrated Cooling and UPS Power Assembly with Control System

(71) Applicants: Aaron Casey, Carrollton, TX (US); Jeffery Riddle, Richardson, TX (US)

(72) Inventors: Aaron Casey, Carrollton, TX (US); Jeffery Riddle, Richardson, TX (US)

(21) Appl. No.: 14/835,887

(22) Filed: Aug. 26, 2015

(51) Int. Cl. H05K 7/20; G06F 11/30; H05K 7/14

(52) U.S. Cl. CPC H05K 7/20836; H05K 7/20145; H05K 7/1492; G06F 11/3044; G06F 11/3058; G06F 11/3062

(57) ABSTRACT

A mobile computer cabinet with integrated cooling and UPS power assembly with control system used to house, cool and provide UPS power to the electronic components and devices within the cabinet. Cooling consists of a door mounted AC panel with associated metal, ceramic or composite baffles, vents, openings and enclosed channels to control the flow of air, dissipate heat, and maintain flow speed, volume and temperature to cool all devices within efficient operational constraints. Power is provided by onboard UPS (uninterruptable power supply) to provide emergency power to the electronic components and the cooling system. The entire assembly is integrated into a standard computer cabinet movable via casters having a single point of connection to the facility.

### CROSS-REFERENCE TO RELATED APPLICATION 35 USC §119(e)

Not Applicable

### FIELD OF INVENTION

This invention relates to the integration of a standard server cabinet, panel air-conditioning (“AC unit”), uninterruptable power supply (“UPS power unit”) and controls, into a mobile system for use in modern data centers and other facilities requiring rack mounted electronics requiring environmental control. The invention includes a method of channeling air to specific electronic devices in the cabinet, emergency back-up fans, air vents, etc; and, control logic to make all components work effectively and efficiently.

### BACKGROUND OF INVENTION

For many decades now telecommunications, cable television and large scale information services companies have constructed and operated “data” centers as central nodes for housing equipment, interconnecting voice and data circuits and storing information in large databases. These data centers have evolved from telephone switching centers and large scale computer rooms to modern day “server farms”.

With the proliferation of the internet, wireless broadband and mobility networks, capacity demands in the central nodes have significantly increased to the point where some of the largest companies find it best to build high capacity facilities near power plants, rivers, electrical power stations to obtain reliable and cost effective energy. In fact, the amount of energy consumed to operate these facilities is so great that building the server farm as close as possible to the energy source is more efficient than suffering the loss of power and efficiency introduced by transmission line loss.

Equipment miniaturization has increased the density of data traffic served by a single chip, computer processor and server array. Increases in fiber optic cable capacity, wireless network expansion and over-all density in deployment of broadband facilities which interconnect building, networks and people has enabled operators to push electronic infrastructure deeper into the market than ever before. Homes, hotels, businesses, retail coffee outlets and even street light poles are suitable for mounting and housing various electronics used for networking across the country.

Several standards for this equipment exist and one of the standards is the dimension of the mounting rack in which servers, radios and optical gear is mounted. Another standard is the operating parameters related to power (voltage and current) and operating temperature (surface and ambient) of the electronics. The present invention introduces a new configuration for integrating the cooling, power, and equipment mounting equipment into a single yet portable cabinet and distributing airflow within the equipment cabinent.

Traditionally, a standard size equipment cabinet was placed inside a “data” center specially designed to provide organized cable access, adequate ambient room temperature for cooling purposes and multiple power supply to ensure continuous operations.

As more equipment moves to the edge of the network, these traditional techniques for housing, cooling and powering equipment cabinet are being compromised. Therefore, a very real purpose is served by the present invention which integrates the equipment cooling and power control within the equipment cabinet without altering the standard shape and dimension of the cabinet as it is dimensioned today. By integrating these common systems into the actual equipment cabinet, the range of possibilities for use of an equipment cabinet greatly increases since the room or location for housing such a cabinet does not require any special modification or equipment to control ambient environmental conditions or power source.

The present invention simplifies the deployment of high density equipment cabinets nearer the edge of the network while also conforming to dimensions required when deploying cabinets in traditional “data” centers. In short, the present invention works equally well in either a central node or remote node location.

Although there are several apparatuses which may have various functions related to the Mobile Computer Cabinet with Integrated Cooling and UPS Power Assembly with Control System, none of these either separately or in combination with each other, teach or anticipate the current invention. Therefore, there remains an unmet need in the field of equipment cabinets with fully integrated mobility, cooling and power control systems. The current invention will fulfill this unmet need.

### SUMMARY OF INVENTION

The following presents a simplified summary in order to provide a basic understanding of some aspects of the disclosed invention. This summary is not an extensive overview, and it is not intended to identify key/critical elements or to delineate the scope thereof. Its sole purpose is to present some concepts in a simplified form as a prelude to the more detailed description that is presented later.

The integration of a standard server cabinet, panel AC unit, UPS power unit and controls, into a mobile system provides operators greater flexibility in deploying electronics requiring rack mounts, temperature control and power reliability. To do so, a cabinet must be suitable in dimension to accept standardize equipment chassis and power supply. Venting, heat dissipation and temperature stability are necessary to ensure proper equipment performance and longevity.

A cabinet must be compatible with standard line-ups, cabling systems and clearances required when deploying cabinets in new or existing data centers, remote nodes or equipment closets. The present invention provides for an integrated cooling, power and control packages which remains compatible with traditional dimensions of equipment cabinet and is therefore compatible during new installations or as expansion to existing installations.

For applications not subject to standard line-ups or other limitations, the present embodiment is not constrained by such standard dimensions and may be deployed in cabinets or enclosures of different dimensions without compromising the functionality of the system described herein.

To provide for the new features of a self-contained, mobile equipment cabinet while also maintaining dimensions for compatibility with traditional cabinets, the present invention was designed to address the method of channeling air to specific electronic devices in the cabinet.

First, the Air Ducting inside the equipment server cabinet was shaped to form and fit within the free space clearances available within a traditional cabinet. This design form provides compatibility with equipment trays, shelves and chassis that are produced according to standards used within the industry.

Second, the Air Ducting was equipped with baffles, vents, and deflectors and other controllable orifices necessary to direct air to cool specific components within the cabinet and to vary the air flow as necessary using a controller system operating fans and the mechanical baffles, vents and deflectors.

Third, the control system and associated fans and variable positioning capabilities of the baffles, vents and deflectors provides for varying the velocity within a column of air to cool specific components in the cabinet more efficiently.

The present invention also provides additional control functionality through additional fans installed as Emergency Back-up Fans on the top panel of a server cabinet along with Integrated UPS power for the fans Pressure activated venting in the bottom panel of the server cabinet.

In the present invention a new integrated control system was required to collectively manage the combination of cooling, venting and power systems as presented herein. This control system must be capable of sensing and controlling system response to heat emissions, surface and ambient air temperatures throughout the cabinet and air flow volume and velocity at various baffles, vents, deflectors or other orifices. Additional control functionality is incorporated to activate and deactivate emergency backup fans when necessary.

The present invention accomplishes directing air to cool specific components in the cabinet through the use of control logic to vary fans and the velocity within a column of air to cool specific components in the cabinet and integrates this sub-system with emergency backup fans on the top panel of a server cabinet, integrated UPS power for the fans and pressure activated venting in the bottom panel of the server cabinet.

The method described herein presents a mechanism which is used in directing air to cool specific components in the cabinet. It's a function of the design of the duct/fan system in conjunction with the specific ducting which is designed to move the air from the back of the cabinet to the front, under the servers while containing it to prevent loss and then aim the air upward across the face of the servers.

When activated, the system varies the velocity within a column of air to cool specific components in the cabinet as a result of the ducting design which separates a single column of air into three columns each moving at a different velocity. The system is equipped with multiple fans that each operate with variable speed control. The integrated control logic controls each fan speed independently to create the three desired velocities within the respective columns of air.

The present embodiment is not constrained by the number of fans equipped into the cabinet. Additional fans, baffles and control logic can be added to function within larger cabinets or enclosures.

Additionally, the cabinet is equipped with back-up fans which are integrated as part of the system and which are powered by the on-board UPS. The quantity and capacity of the fans is matched to the volume of the cabinet and the pressure required to actuate the associated vent to open at predefined thresholds consistent with maintaining the operating temperature within the cabinet. The present invention introduces this venting functionality to the equipment cabinet as part of the system and this vent, which is separate from the cooling fans, is activated by negative pressure inside the cabinet produced by the emergency fans. When the vent is in the normal “closed” mode, gravity alone acting on the vent closes the vent.

The present invention integrates a series of sensors to provide response inputs to the control logic for system control. These sensors provide for monitoring, scaling and signaling to the control system incorporated into the system design.

Still other objects of the present invention will become readily apparent to those skilled in this art from the following description wherein there is shown and described the embodiments of this invention, simply by way of illustration of the best modes suited to carry out the invention. As it will be realized, the invention is capable of other different embodiments and its several details are capable of modifications in various obvious aspects all without departing from the scope of the invention. Accordingly, the drawing and descriptions will be regarded as illustrative in nature and not as restrictive.

### BRIEF DESCRIPTION OF THE DRAWINGS

Various exemplary embodiments of this invention will be described in detail, wherein like reference numerals refer to identical or similar components, with reference to the following figures, wherein:

FIG. 1 is a perspective view of preferred embodiment illustrating an equipment cabinet assembly including an integrated air conditioning system, UPS, CPU's, controllers and corresponding ducting system.

FIG. 2 is a perspective view of preferred embodiment integrated system illustrating air conditioning unit, UPS unit, vertical, horizontal, and riser duct system and brush seal.

FIG. 3 is a perspective view of preferred embodiment of an air flow handling system illustrating ducting, channels, vents, openings, baffles, fans and sensors for temperature and pressure sensors.

FIG. 4 is a perspective view of the preferred embodiment of an emergency vent system illustrating emergency fans and vents.

FIG. 5 is a perspective view of the preferred embodiment illustrating multiple separate vertical air flow columns within the equipment cabinet.

### DETAILED DESCRIPTION

The claimed subject matter is now described with reference to the drawings. In the following description, for purposes of explanation, numerous specific details are set forth in order to provide a thorough understanding of the claimed subject matter. It may be evident; however, that the claimed subject matter may be practiced with or without any combination of these specific details, without departing from the spirit and scope of this invention and the claims.

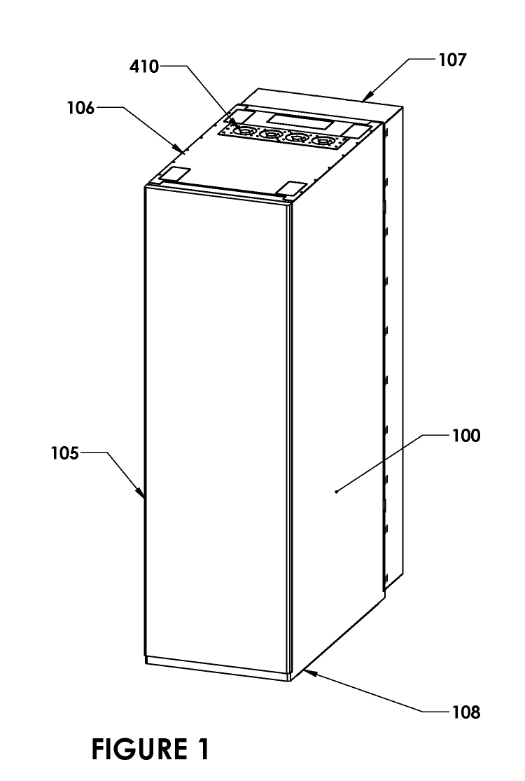

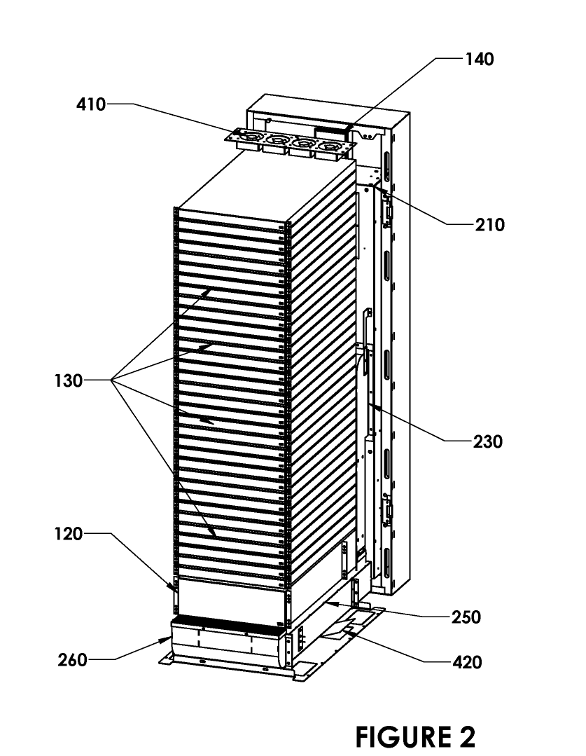

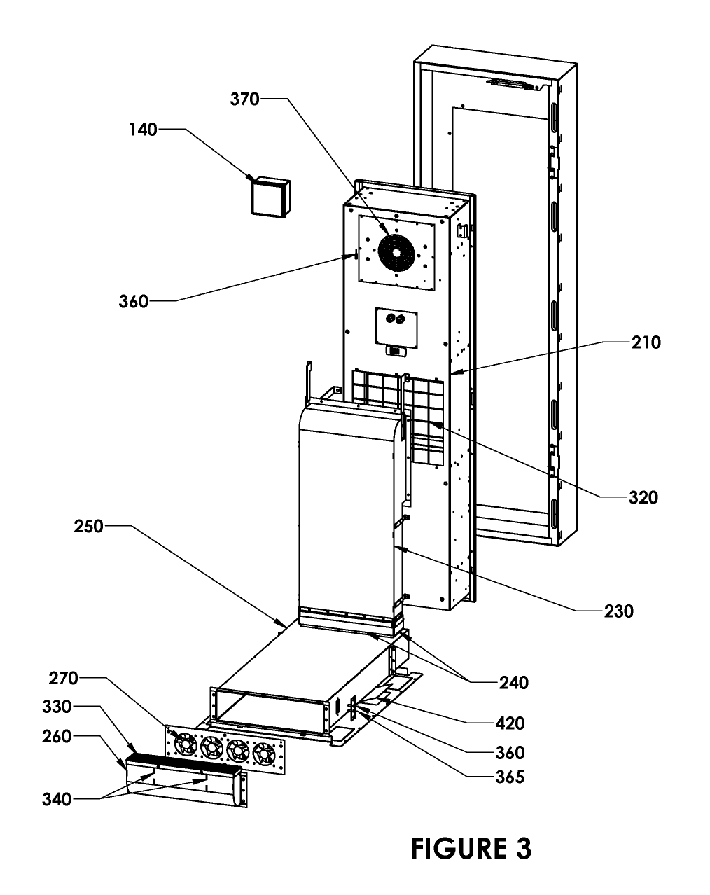

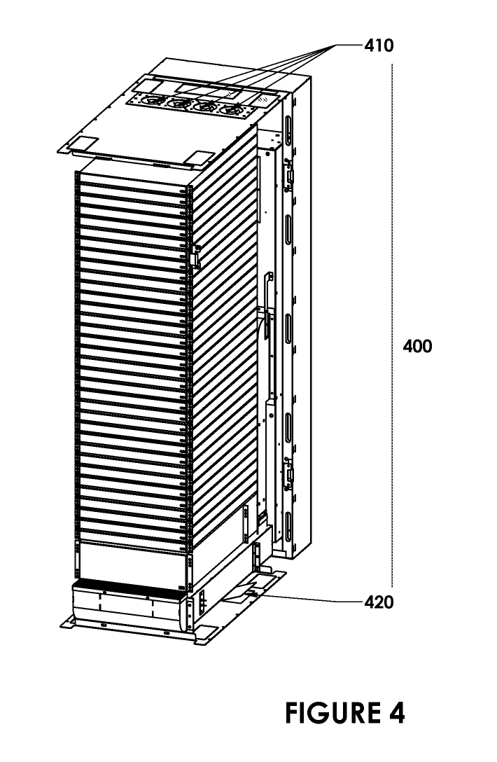

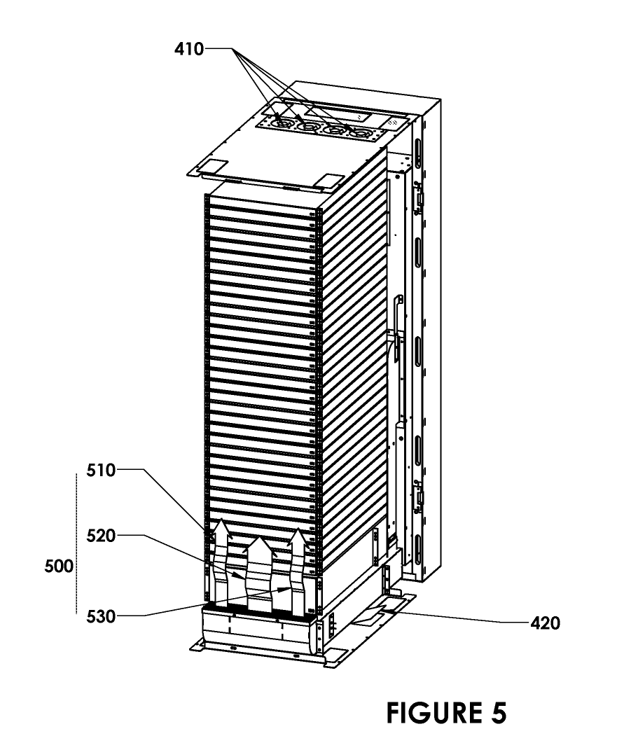

FIG. 1 illustrates a typical data center equipment cabinet 100 with front door 105, rear door 107, top 106 and bottom 108; populated with an air cooling unit 210 FIG. 2, uninterruptable power supply (UPS) 120 FIG. 2, multiple computing processors devices (CPUs) 130 FIG. 2 and a system controller 140 FIG. 2, ducts 230, 250 and 260 FIG. 3, emergency fans and vents 410 and 420 FIG. 4; including but not limited to, baffles 340 FIG. 3 forming columnized air channels 500, shown as 510, 520, and 530 FIG. 5 representing the present embodiment presented herein. The equipment cabinet 100 illustrated in FIG. 1 has dimension conforming to the standard dimensions of equipment cabinets deployed in data centers, remote network nodes and equipment closets typically deployed in modern data and voice networks. While the present embodiment is not limited to conforming dimension of traditional equipment cabinet footprint specifications, the present embodiment is deployable as conforming to these specifications.

The equipment cabinet shown in FIG. 1 is configured with an air cooling unit 210 FIGS. 2 and 3. This air cooling unit 210 provides regulated temperature air flow directed throughout the equipment cabinet 100. The purpose of the air cooling unit 210 is to regulate the temperature, humidity and velocity of air circulating within the equipment cabinet 100 to maintain ambient, near surface and overall temperature within the equipment cabinet 100 and the CPUs 130 FIG. 2 mounted therein.

Traditional methods for providing air cooling for such equipment has been to co-locate centralized air cooling and handling systems within a data center to cool the entire volume of air within the room where equipment cabinets. In such deployments, ambient air external to the equipment cabinet is drawn into the equipment cabinet and circulated therein to cool various components mounted within the equipment cabinet eventually discharged back into the room or vented external to the room. In such deployments, the centralized air cooling and handling systems are dimensioned to maintain environmental stability for the entire room.

The present embodiment illustrates how to incorporate an air cooling system 210 FIGS. 2 and 3 within the equipment cabinet 100 FIG. 1. By incorporating the air cooling system 210 as an integral part of the equipment cabinet 100, the air cooling system 210 and associated duct system as shown in 230, 240, 250 and 260 FIG. 3 become part of the form and function of the equipment cabinet 100. Such an equipment cabinet 100 consisting of air cooling 210, ducts systems 230, 250 and 260, and air brush system 240 as presented herein, can be deployed in locations with or without environmental control of the air envelop of the deployment location. Accordingly, the costs for deployment of equipment cabinets 100 decrease due to the avoidance costs of having to construct and equip equipment rooms with air conditioning of the air envelop within the room.

FIGS. 1 and 2 also illustrates the preferred present embodiment comprised of the equipment cabinet and the UPS system 120 FIG. 2. Equipment cabinets 100 FIG. 1 function to contain mounted CPUs 130 FIG. 2. These CPUs 130 are typically services, radios and other similar products which consist of memory, processors, software, electrical and radio frequency interfaces which in combination form networks, nodes, controllers or data storage elements utilized in a wide variety of applications. Since these CPUs 130 are typically high density electrical devices and systems, very high electrical power requirements are present. Also, during operation, the CPUs 130 use of power generates heat that must be dissipated during normal and emergency conditions.

The UPS system 120 shown in FIG. 2 illustrates how the form and function of the UPS system 120 is also integrated with the form and function of the equipment cabinet 100 FIG. 1. Similar to the traditional air cooling and handling systems typically deployed in equipment room as described above, centralized power and UPS systems are also typically centralized at the same location. Accordingly, electrical cabling, conduit, junctions and distribution panels are required to route electrical connections between traditional equipment cabinets and the centralized systems. In the present embodiment, these additional devices and associated costs are also avoided as a result of integrating the UPS system 120 into the equipment cabinet 100 form and function.

In FIGS. 2 and 3, the controller 140 is illustrated within the equipment cabinet 100 FIG. 1. Since the present embodiment integrates the air cooling system 210 FIGS. 2 and 3 and UPS system 120 FIG. 2 into the form and function of the equipment cabinet 100, control of the integrated system is required and therefore provided by the controller 140.

As shown in FIG. 3, the controller 140 controls the airflow control system 210 which consists of ducts 230, 250, 260 and brush 240 to route air to regulate air flow in conjunction with fans 270, returning to vent 360. Additionally, baffles 340 are placed within the ducting to channel air flow, into separate channels 510, 520 and 530 forming the columnized air flow 500 within the cabinet as shown in FIG. 5, and to regulate air flow velocity in conjunction with the fans 270 FIGS. 3 and 410 FIG. 2, vents 320, 330, 360, 420 and the controller 140 FIG. 3.

As shown in FIG. 3, various temperature 360 and pressure 365 sensors are deployed with the air control system 210 and duct 250 FIG. 3. These sensors 360 and 365 detect and report measurements to the controller 140 FIG. 3. The logic integrated into the controller 140 implemented in hardware, firmware and software within the controller processes the signals according to the controller 140 design to generate control signals to the fans 270 and emergency system 400 consisting of emergency fans 410 and vents 420 FIG. 4.

FIG. 4 illustrates the emergency system 400 integrated with the equipment cabinet 100 FIG. 1. The emergency system 400 is controlled by sensors 360 and 365 and the controller 140 FIG. 3. Under conditions which can be defined as an emergency condition by the user, the emergency system 400 will activate to engage additional fans 410 which will actuate vents 420. Under emergency conditions, and upon controller 140 or sensor 360 and 365 signal, the emergency fans 410 will activate to increase the intake and exhaust of additional air from the surrounding environment.

As shown in FIG. 4, in the event temperature rises within the equipment cabinet 100, emergency fans 410 will activate to draw additional air into the cabinet 100 through vents 420 located in the floor of the equipment cabinet 100 FIG. 1. The fans 410 located on the top of the equipment cabinet 100 will draw additional air from the exterior of the equipment cabinet 100 through vent 420, which consists of a flap held closed only by the force of gravity acting upon the flap itself. As additional air enters the open vent 420, temperature within the cabinet is reduced. During this emergency venting process, the temperature with the cabinet 100 is normalized to the temperature of the ambient air external to the equipment cabinet 100 which is further cooled by the mixing of cooled air present within the equipment cabinet 100 at the time. Continued operation of the emergency fans will decrease as the temperature as detected by sensors 360 and 365 return to thresholds defined in the controller 140. At an appropriate environmental state, the emergency vent 420 will close by the force of gravity as the fans 410 speed diminishes at which point the emergency condition has subsided.

In FIG. 5 illustrates the columnization of air into three separate air flow columns 510, 520, and 530 forming columnized air flow 500 presented in the present embodiment. This feature of specific columnization feature is accomplished by channeling air flow from the air cooling system 210 through the supply vent 320 of the air cooling system 210 FIG. 3. The fans 270 move the cooled air through the vertical ducts 230 and across air flow brushes 240, and through horizontal duct 250 which forms the base of the equipment cabinet 100 FIG. 1. The cooled air flows through the horizontal duct 250 to the front of the equipment cabinet 100 through the riser duct 260 which directs the cooled air upwards. The riser duct 260 has baffles 340 FIG. 3 and corresponding fans 270 positioned to separate cooled air into separate columns 510, 520 and 530 FIG. 5. The air flow velocity within each air flow column is independently controlled by the controller 140 operating the corresponding fan 270 FIG. 3 speed of each respective column. The various air flow columns are then channeled up and through riser duct 260 to openings 330 where upon exhaust flows over, around and by the CPUs 130 FIG. 2 mounted within the equipment cabinet 100 FIG. 1. Eventually, the air will undergo heat transfer thermodynamic process to dissipate the heat emitted from the CPUs 130 before being returned to the air cooling system 210 through the return vent 370 of the air cooling system 210 FIG. 3.

It may be advantageous to set forth definitions of certain words and phrases used in this patent document. The term “couple” and its derivatives refer to any direct or indirect communication between two or more elements, whether or not those elements are in physical contact with one another. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

What has been described above includes examples of the claimed subject matter. It is, of course, not possible to describe every conceivable combination of components or methodologies for purposes of describing the claimed subject matter, but one of ordinary skill in the art can recognize that many further combinations and permutations of such matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

We claim,

1. An improved integrated variable air flow configuration assembly and management system used to cool and distribute air within the equipment cabinet and to components and assemblies of electronic devices mounted within the equipment cabinet positioned within a data center, equipment room, closet or outdoor enclosure, having metal, ceramic or composite form with shapes in the form of baffles, vents, openings, enclosed channels to direct the flow of air, dissipate heat, maintain flow volume and temperature according to parameters of the management system within efficient operational constraints to achieve desired equipment performance, longevity and cost effectiveness:
1. A mobile computer cabinet with integrated cooling and UPS power assembly with control system used to house, cool and provide UPS power to the electronic components and devices within the cabinet.
2. An equipment cabinet with integrated air cooling and air flow control system using channels, vents, openings, baffles and fans to circulate columnized air flow throughout the equipment cabinet to cool by dissipating heat generated by electronic devices and assemblies mounted in the cabinet wherein each column of forced air is separately controlled within the cabinet by integrated a control logic system.
3. An electronic system for controlling cooling and emergency cooling comprising:
A memory storing instructions; and,
at least one processor configured to execute the instructions;
at least one sensor(s) to detect air temperature within the cabinet;
at least one sensor(s) to detect proper operation of the AC panel;
A management system to detect and generate a response to activate air cooling system; generate a response to activate and control fan speed; generate a response to control dampers, vents or openings through which air flow can be controlled; generate a response to control variable controls of operation of the variable cooling system; generate a response to control activation of emergency cooling in case of AC failure; and, generate a response to maintain operation of the integrated systems to achieve cost efficiencies of the operational system.
4. An airflow system containing channels, baffles, variable speed fans and openings through which air flow velocity, volume and temperature are controlled and directed to specific components within the cabinet in order to cool all devices within efficient operational constraints.
5. An emergency cooling system powered by UPS power supply with variable speed DC cooling fans and pressure activated venting.
